(19) United States
(12) Patent Application Publication
(10) Pub. No.: US 2024/0395573 A1
(43) Pub. Date: Nov. 28, 2024

(54) BONDING METHOD AND BONDING SYSTEM

(71) Applicant: Tokyo Electron Limited, Tokyo (JP)

(72) Inventors: Atsushi Nagata, Koshi City (JP); Takuro Masuzumi, Koshi City (JP); Norifumi Kohama, Koshi City (JP); Hayato Tanoue, Koshi City (JP)

(21) Appl. No.: 18/671,145

(22) Filed: May 22, 2024

(30) Foreign Application Priority Data
May 23, 2023 (JP) 2023-084846

(51) Int. Cl. H01L 21/67; H01L 21/66; H01L 21/683

(52) U.S. Cl. CPC H01L 21/67092; H01L 21/683; H01L 22/12

(57) ABSTRACT

A bonding method of bonding substrates to each other includes forming a combined substrate by gradually bonding, with a central portion of a first substrate and a central portion of a second substrate in contact with each other, the first substrate and the second substrate from the central portions toward outer peripheral portions thereof; measuring a bonding speed in the bonding from the central portions toward the outer peripheral portions; and estimating, based on the measured bonding speed, bonding strength of the bonded combined substrate from a relationship between bonding speed and bonding strength.

### CROSS-REFERENCE TO RELATED APPLICATION

This application claims the benefit of Japanese Patent Application No. 2023-084846 filed on May 23, 2023, the entire disclosure of which is incorporated herein by reference.

### TECHNICAL FIELD

The various aspects and embodiments described herein pertain generally to a bonding method and a bonding system.

### BACKGROUND

Patent Document 1 discloses a bonding apparatus for bonding wafers to each other. This bonding apparatus has an upper chuck configured to attract and hold an upper wafer, and a lower chuck provided below the upper chuck and configured to attract and hold a lower wafer. In the bonding apparatus, the two wafers are disposed to face each other in a vertical direction and are bonded together to form a combined wafer.

Patent Document 1: Japanese Patent Laid-open Publication No. 2017-073455

### SUMMARY

In an exemplary embodiment, a bonding method of bonding substrates to each other includes forming a combined substrate by gradually bonding, with a central portion of a first substrate and a central portion of a second substrate in contact with each other, the first substrate and the second substrate from the central portions toward outer peripheral portions thereof; measuring a bonding speed in the bonding from the central portions toward the outer peripheral portions; and estimating, based on the measured bonding speed, bonding strength of the bonded combined substrate from a relationship between bonding speed and bonding strength.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view schematically illustrating a configuration of a bonding system according to an exemplary embodiment;

FIG. 2 is a side view schematically illustrating structures of an upper wafer and a lower wafer;

FIG. 3 is a cross sectional view schematically illustrating a configuration of a surface modifying apparatus;

FIG. 4 is a cross sectional view schematically illustrating a configuration of a bonding apparatus;

FIG. 5 is a cross sectional view schematically illustrating configurations of an upper chuck and a lower chuck;

FIG. 6 is an explanatory diagram illustrating main processes of a wafer processing;

FIG. 7A to FIG. 7F are explanatory diagrams illustrating main processes of a wafer bonding processing;

FIG. 8 is an explanatory diagram illustrating measurement of bonding speed;

FIG. 9 is an explanatory diagram illustrating arrangement of sensors;

FIG. 10 is an explanatory diagram illustrating a relationship between bonding speed and bonding strength;

FIG. 11 is an explanatory diagram illustrating how a combined wafer warps;

FIG. 12 is an explanatory diagram illustrating a reason why the combined wafer warps; and

FIG. 13 is an explanatory diagram illustrating a relationship between a warpage amount and bonding strength.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In three-dimensional integration technology for stacking semiconductor devices in three dimensions, two sheets of semiconductor wafers (hereinafter simply referred to as “wafers”) are bonded to each other. In the bonding processing, the wafers are bonded to each other by, for example, a van der Waals force and a hydrogen bond (intermolecular force).

In the bonding apparatus disclosed in Patent Document 1, a central portion of a front surface of the upper wafer held by the upper chuck is pressed down by a pressing pin to be brought into contact with a central portion of a front surface of the lower wafer held by the lower chuck. Then, bonding due to the aforementioned intermolecular force is started between the pressed central portions of the front surfaces of the upper and lower wafers. Then, evacuation of the upper wafer is stopped from the central portion of the upper wafer toward an outer periphery thereof, so that the upper wafer gradually falls onto the lower wafer and comes into contact with it, and the bonding due to the intermolecular force gradually expands on the entire front surfaces of the upper and lower wafers. As a result, the surface of the upper wafer and the surface of the lower wafer come into contact with each other on the entire surfaces thereof, so that the upper wafer and the lower wafer are bonded to form a combined wafer.

Bonding strength between the upper wafer and the lower wafer in the combined wafer affects the quality of the combined wafer. Conventionally, it has been known to use a so-called blade insertion method to measure the bonding strength of the combined wafer. In the blade insertion method, a measurement wafer that does not have a pattern formed on a surface thereof, which is different from a product wafer, is used. After bonding measurement wafers, a blade is inserted into a bonding interface from an end of a combined measurement wafer. Then, a crack that occurs when the end of the combined measurement wafer is opened is imaged, and the length of the crack in a diametrical direction is measured. Then, bonding energy is calculated from the measured length of the crack in the diametrical direction by using a known equation.

When using the blade insertion method, however, the measurement wafer is damaged due to the insertion of the blade, so this measurement wafer is discarded and cannot be reused, which is wasteful. Also, since the wafer used is damaged in the blade insertion method, a product wafer and a high-price patterned wafer cannot be used, so a simple measurement wafer without a pattern is used. In this case, it is difficult to measure actual bonding strength, and in this regard, there is a room for improvement in measurement accuracy.

The present disclosure provides a technique capable of simply estimating bonding strength of a combined substrate in which substrates are bonded to each other. Hereinafter, a bonding system and a bonding method according to an exemplary embodiment will be described with reference to the accompanying drawings. Further, in the present specification and the various drawings, parts having substantially same functions and configurations will be assigned same reference numerals, and redundant description will be omitted.

### Configuration of Bonding System

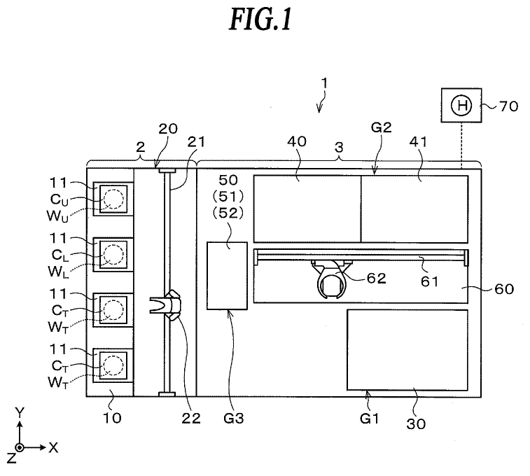

First, a configuration of a bonding system according to the present exemplary embodiment will be described. FIG. 1 is a plan view schematically illustrating a configuration of a bonding system 1 according to the present exemplary embodiment. Further, in the following, to clarify positional relationships, the X-axis, Y-axis and Z-axis which are orthogonal to each other will be defined. The positive Z-axis direction will be regarded as a vertically upward direction.

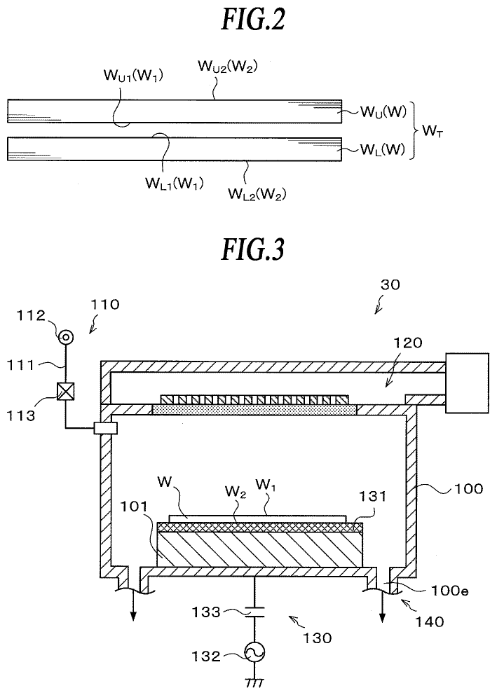

In the bonding system 1, wafers W_{U} and W_{L} as substrates shown in FIG. 2 are bonded to each other. Hereinafter, a wafer disposed at the upper side in a bonding apparatus 41 to be described later is referred to as “upper wafer W_{U}” as a first substrate, and a wafer disposed at the lower side is referred to as “lower wafer W_{L}” as a second substrate. Further, in the upper wafer W_{U}, a surface to be bonded to the lower wafer W_{L} is referred to as “front surface W_{U1},” and a surface opposite to the front surface W_{U1} is referred to as “rear surface W_{U2}.” Likewise, in the lower wafer W_{L}, a surface to be bonded to the upper wafer W_{U} is referred to as “front surface W_{L1},” and a surface opposite to the front surface W_{L1} is referred to as “rear surface W_{L2}.” In the following, the upper wafer W_{U} and the lower wafer W_{L} may also be collectively referred to as “wafer W.” Further, the front surface W_{U1} of the upper wafer W_{U} and the front surface W_{L1} of the lower wafer W_{L} may also be collectively referred to as “front surface W₁.” Likewise, the rear surface W_{U2} of the upper wafer W_{U} and the rear surface W_{L2} of the lower wafer W_{L} may also be collectively referred to as “rear surface W₂.” In the bonding system 1, the upper wafer W_{U} and the lower wafer W_{L} are bonded to each other to form a combined wafer W_{T} as a combined substrate.

As shown in FIG. 1, the bonding system 1 has a configuration in which a carry-in/out station 2 and a processing station 3 are connected as one body. In the carry-in/out station 2, cassettes C_{U}, C_{L} and C_{T} capable of accommodating therein a plurality of upper wafers W_{U}, lower wafers W_{L} and combined wafers W_{T}, respectively, are carried to/from, for example, the outside. The processing station 3 is equipped with various types of processing apparatuses configured to perform required processings on the upper wafer W_{U}, the lower wafer W_{L}, and the combined wafer W_{T}.

A cassette placing table 10 is provided in the carry-in/out station 2. A plurality of, for example, four cassette placing plates 11 are provided on the cassette placing table 10. These cassette placing plates 11 are arranged in a row in the Y-axis direction. The cassettes C_{U}, C_{L}, and C_{T} can be arranged on these cassette placing plates 11 when the cassettes C_{U}, C_{L}, and C_{T} are carried to/from the outside of the bonding system 1. Further, the number of the cassette placing plates 11 is not limited to the example of the present exemplary embodiment, but can be selected as required.

In the carry-in/out station 2, a wafer transfer section 20 is provided adjacent to the cassette placing table 10 on the positive X-axis side of the cassette placing table 10. The wafer transfer section 20 is provided with a wafer transfer device 22 configured to be movable on a transfer path 21 which extends in the Y-axis direction. This wafer transfer device 22 is capable of transferring the upper wafer W_{U}, the lower wafer W_{L}, and the combined wafer W_{T} between the cassettes C_{U}, C_{L}, and C_{T} on the respective cassette placing plates 11, transition devices 50 and 51 to be described later, and a warpage measurement device 52 to be described later.

The processing station 3 is provided with a plurality of, for example, three processing blocks G1, G2 and G3, equipped with various types of devices. For example, a first processing block G1 is provided on the negative Y-axis side of the processing station 3, and a second processing block G2 is provided on the positive Y-axis side of the processing station 3. Additionally, a third processing block G3 is provided on the negative X-axis side of the processing station 3.

The first processing block G1 is equipped with a surface modifying apparatus 30 configured to modify the front surface W₁ of the wafer W. In the second processing block G2, a surface hydrophilizing apparatus 40 configured to hydrophilize and clean the front surface W₁ of the wafer W and a bonding apparatus 41 configured to bond the upper wafer W_{U} and the lower wafer W_{L} are arranged in the X-axis direction. In the third processing block G3, the transition devices 50 and 51 configured to temporarily accommodate therein the upper wafer W_{U}, the lower wafer W_{L}, and the combined wafer W_{T}, and the warpage measurement device 52 as a warpage measurer configured to measure a warpage amount of the combined wafer W_{T} are stacked on top of each other.

In the surface hydrophilizing apparatus 40, pure water is supplied onto the front surface W₁ of the wafer W while rotating the wafer W held on, for example, a spin chuck. Then, the supplied pure water is diffused on the front surface W₁ of the wafer W, so that the front surface W₁ is hydrophilized. Further, the above-described configuration is just an example, and the surface hydrophilizing apparatus 40 may have any of various configurations as long as it is capable of hydrophilizing the front surface W₁ of the wafer W. Further, the configurations of the surface modifying apparatus 30 and the bonding apparatus 41 will be described later.

The transition devices 50 and 51 temporarily accommodates therein the upper wafer W_{U}, the lower wafer W_{L}, and the combined wafer W_{T} to deliver these upper, lower and combined wafers W_{U}, W_{L}, and W_{T} between the wafer transfer device 22 of the wafer transfer section 20 and a wafer transfer device 62 of a wafer transfer section 60 to be described later. The warpage measurement device 52 measures a warpage amount of the bonded combined wafer W_{T}. The configuration of the warpage measurement device 52 is arbitrary; for example, the warpage amount of the combined wafer W_{T} is measured using a displacement meter.

The wafer transfer section 60 is provided in an area surrounded by the first to third processing blocks G1 to G3. The wafer transfer section 60 is provided with the wafer transfer device 62 configured to be movable on a transfer path 61 extending in the X-axis direction. The wafer transfer device 62 is capable of transferring the upper wafer W_{U}, the lower wafer W_{L}, and the combined wafer W_{T} to/from the surface modifying apparatus 30, the surface hydrophilizing apparatus 40, the bonding apparatus 41, the transition devices 50 and 51, and the warpage measurement device 52.

The above-described bonding system 1 is equipped with a control device 70. The control device 70 is implemented by, for example, a computer equipped with a CPU, a memory, etc., and includes a non-illustrated program storage. A program for controlling a wafer processing in the bonding system 1 is stored in the program storage. Further, the program may have been recorded in a computer-readable recording medium H, and may be installed from this recording medium H into the control device 70. In addition, the recording medium H may be transitory or non-transitory.

### Configuration of Surface Modifying Apparatus

In the above-described surface modifying apparatus 30, an oxygen gas or a nitrogen gas as a processing gas is excited into plasma in, for example, a decompressed atmosphere to be ionized. The oxygen ions or nitrogen ions are radiated onto the front surface W₁ of the wafer W, and, thus, the front surface W₁ is plasma-processed to be modified.

As shown in FIG. 3, the surface modifying apparatus 30 includes a processing container 100, a processing gas supply 110, a plasma generator 120, an ion attraction device 130, and an exhaust device 140.

The processing container 100 has a hermetically sealable inside. A non-illustrated carry-in/out opening for the wafer W is formed at the processing container 100, and the carry-in/out opening is provided with a non-illustrated gate valve. A stage 101 configured to attract and hold the rear surface W₂ of the wafer W such that the front surface W₁ of the wafer W faces upwards is placed at a bottom portion of the processing container 100. For example, at least a part of the stage 101 is formed of an insulating member.

The processing gas supply 110 is configured to supply a processing gas into the processing container 100. The processing gas supply 110 includes a gas supply path 111, at least one gas source 112 and at least one flow rate controller 113 configured to introduce the processing gas into the processing container 100. The gas supply path 111 is configured to introduce the processing gas supplied from the gas source 112 into the processing container 100. The flow rate controller 113 may include, for example, a mass flow controller or a pressure control type or a flow rate modulation device. Also, the processing gas supplied from the gas source 112 is not limited to the oxygen gas or the nitrogen gas. For example, an argon gas or a helium gas may be supplied.

The plasma generator 120 is configured to generate plasma of the processing gas inside the processing container 100. In the illustrated example, the plasma generator 120 is equipped with a surface wave plasma (SWP) generating apparatus. However, the configuration of the plasma generator 120 is not particularly limited, and the plasma generator 120 may be configured by one of a capacitively coupled plasma (CCP) generating apparatus, an inductively coupled plasma (ICP) generating apparatus, and electron-cyclotron-resonance plasma (ECR plasma) generating apparatus and a helicon wave plasma (HWP) generating apparatus. Alternatively, various types of plasma generators including an alternating current (AC) plasma generator and a direct current (DC) plasma generator may be used.

The ion attraction device 130 is configured to attract the ions distributed in the plasma generated inside the processing container 100 onto the front surface W₁ of the wafer W on the stage 101. In an example, the ion attraction device 130 includes at least one electrode 131, a high frequency power supply 132, and a capacitor 133. The high frequency power supply 132 may also be used to generate plasma inside the processing container 100 as well as to attract the ions onto the front surface W₁ of the wafer W. Therefore, the high frequency power supply 132 supplies at least one of a source power or a bias power to the electrode 131.

The exhaust device 140 is connected to, for example, a gas exhaust opening 100e provided at a bottom portion of the processing container 100. The exhaust device 140 may include a pressure adjusting valve and a vacuum pump. An internal pressure of the processing container 100 is adjusted by the pressure adjusting valve. The vacuum pump may include a turbo molecular pump, a dry pump, or a combination thereof.

The surface modifying apparatus 30 is configured as described above. The above-described configuration is just an example, and the surface modifying apparatus 30 may have any configuration as long as it can modify the front surface W₁ of the wafer W.

### Configuration of Bonding Apparatus

In the above-described bonding apparatus 41, the upper wafer W_{U} and the lower wafer W_{L} are bonded on their front surfaces W_{U1} and W_{L1}, each of which have been sequentially subjected to a surface modifying processing and a surface hydrophilizing processing.

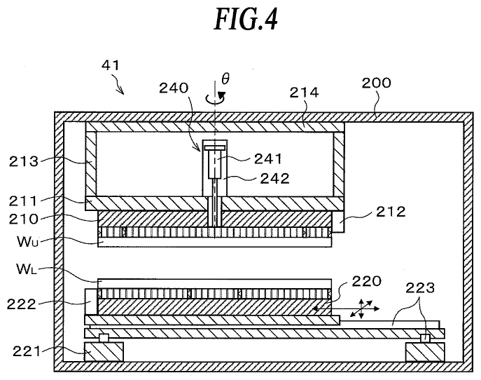

As shown in FIG. 4, the bonding apparatus 41 includes a processing container 200, an upper chuck 210, and a lower chuck 220.

The processing container 200 has a hermetically sealable inside. A non-illustrated carry-in/out opening for the wafer W is formed at the processing container 200, and the carry-in/out opening is provided with a non-illustrated gate valve. The upper chuck 210 is placed at a ceiling portion of the processing container 200, and the lower chuck 220 is placed at a bottom portion of the processing container 200.

The upper chuck 210 is configured to attract and hold the rear surface W_{U2} of the upper wafer W_{U} on a lower surface thereof. The upper chuck 210 is supported by an upper chuck stage 211 provided on the upper chuck 210. The upper chuck stage 211 is equipped with an upper imaging device 212 configured to image the front surface W_{L1} of the lower wafer W_{L} held by the lower chuck 220. For example, a CCD camera is used as the upper imaging device 212.

The upper chuck stage 211 is supported on a rotating device 214 above, which is provided on a ceiling surface of the processing container 200 with a plurality of supporting members 213 therebetween. The rotating device 214 is configured to rotate the upper chuck stage 211 and the upper chuck 210 around a vertical axis (θ-axis). Also, the rotating device 214 may be provided with a non-illustrated measurement device (for example, a linear scale) configured to measure a position of the upper chuck 210 in the θ-axis direction.

The lower chuck 220 is configured to attract and hold the rear surface W_{L2} of the lower wafer W_{L} on a top surface thereof. The lower chuck 220 is provided under the upper chuck 210 and configured to be arranged to face the upper chuck 210. That is, the upper wafer W_{U} held by the upper chuck 210 and the lower wafer W_{L} held by the lower chuck 220 are arranged to face each other. The lower chuck 220 is supported by a lower chuck stage 221 provided under the lower chuck 220. The lower chuck stage 221 is equipped with a lower imaging device 222 configured to image the front surface W_{U1} of the upper wafer W_{U} held by the upper chuck 210. For example, a CCD camera is used as the lower imaging device 222.

The lower chuck 220 is also equipped with a moving device 223. The moving device 223 is configured to move the lower chuck stage 221 and the lower chuck 220 in a horizontal direction. Further, the moving device 223 is configured to move the lower chuck 220 in a vertical direction. Furthermore, the moving device 223 may be equipped with a non-illustrated measurement device (for example, a laser interferometer system) configured to measure a position of the lower chuck 220 in the horizontal direction and a position of the lower chuck 220 in the vertical direction.

Now, detailed configurations of the upper chuck 210 and the lower chuck 220 described above will be explained together with members around them.

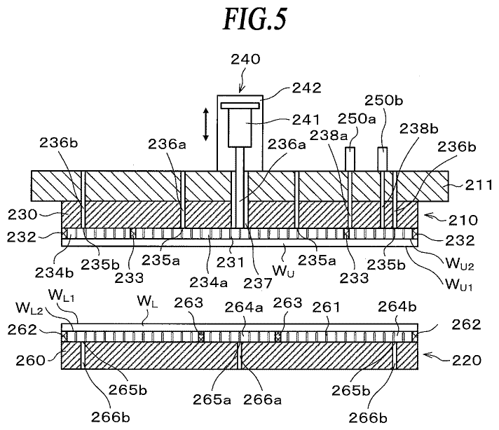

As shown in FIG. 5, the upper chuck 210 is of a pin chuck type. The upper chuck 210 has a main body 230 having a diameter equal to or larger than the diameter of the upper wafer W_{U} when viewed from the top. A plurality of pins 231 are provided on a bottom surface of the main body 230 to be in contact with the rear surface W_{U2} of the upper wafer W_{U}. Further, an outer rib 232 having the same height as the pins 231 is provided at an outer peripheral portion of the bottom surface of the main body 230 to support an outer peripheral portion of the rear surface W_{U2} of the upper wafer W_{U}. The outer rib 232 is provided in an annular shape outside the plurality of pins 231.

Further, on the bottom surface of the main body 230, an inner rib 233 having the same height as the pins 231 is provided inside the outer rib 232 to support the rear surface W_{U2} of the upper wafer W_{U}. The inner rib 233 is provided in an annular shape to be concentric with the outer rib 232. Further, an area 234 (hereinafter, sometimes referred to as suction area 234) inside the outer rib 232 is partitioned into a first suction area 234a inside the inner rib 233 and a second suction area 234b outside the inner rib 233.

A first suction opening 235a for evacuating the upper wafer W_{U} in the first suction area 234a is formed in the bottom surface of the main body 230. For example, the first suction opening 235a is plural in number, and these first suction openings 235a are formed at multiple locations in the first suction area 234a, for example. A first suction pipe 236a provided inside the main body 230 is connected to the first suction opening 235a. Further, a non-illustrated vacuum pump is connected to the first suction pipe 236a.

Further, a second suction opening 235b for evacuating the upper wafer W_{U} in the second suction area 234b is also formed in the bottom surface of the main body 230. For example, the second suction opening 235b is plural in number, and these second suction openings 235b are formed at multiple locations in the second suction area 234b. A second suction pipe 236b provided inside the main body 230 is connected to the second suction opening 235b. Further, a non-illustrated vacuum pump is connected to the second suction pipe 236b.

The suction areas 234a and 234b surrounded by the upper wafer W_{U}, the main body 230, and the outer rib 232 are decompressed by being evacuated through the suction openings 235a and 235b, respectively. The upper chuck 210 is configured to be capable of attracting and holding the upper wafer W_{U} in each of the first suction area 234a and the second suction area 234b individually.

A through hole 237 is formed through a center of the main body 230 of the upper chuck 210 and a center of the upper chuck stage 211 in a thickness direction. The center of the main body 230 corresponds to a center of the upper wafer W_{U} held by the upper chuck 210. An actuator 241 of a pressing device 240 to be described later is inserted into the through hole 237.

Ina peripheral portion of the main body 230 of the upper chuck 210 and a peripheral portion of the upper chuck stage 211, two transmission windows 238a are formed to penetrate the main body 230 and the upper chuck stage 211 in the thickness direction. The first transmission window 238a and the second transmission window 238b are arranged in this order from an inner side toward an outer side in a diametrical direction. The transmission windows 238a and 238b are made of, for example, quartz, and transmit LED lights radiated from sensors 250a and 250b to be described later.

The pressing device 240 configured to press the center of the upper wafer W_{U} from the rear surface W_{U2} side is provided at a center of a top surface of the upper chuck stage 211. The pressing device 240 has the actuator 241 and a cylindrical member 242.

The actuator 241 is configured to be vertically movable up and down through the through hole 237 by air from an electropneumatic regulator, for example. The actuator 241 is brought into contact with the center of the upper wafer W_{U} by the air from the electropneumatic regulator, and can control a press load applied to the center of the upper wafer W_{U}.

The actuator 241 is supported by the cylindrical member 242. The cylindrical member 242 is configured to move the actuator 241 in a vertical direction by a driver having therein a motor, for example.

As described above, the pressing device 240 controls the press load by the actuator 241, and controls the movement of the actuator 241 by the cylindrical member 242. Also, the pressing device 240 can bring the center of the upper wafer W_{U} and the center of the lower wafer W_{L} into contact with each other and pressurize them when bonding the wafers W_{U} and W_{L} as will be described later.

A plurality of, for example, two sensors 250a and 250b are provided at peripheral portions of the upper chuck stage 211. The first sensor 250a and the second sensor 250b are arranged in this order from the inner side toward the outer side in the diametrical direction. The first sensor 250a is disposed to correspond to the first transmission window 238a, and the second sensor 250b is disposed to correspond to the second transmission window 238b.

The sensors 250a and 250b measure a height position of the rear surface W_{U2} of the upper wafer W_{U}. Measurement results of the sensors 250a and 250b are outputted to the control device 70, and the control device 70 calculates bonding speed (propagation speed of a bonding wave) based on the height position of the rear surface W_{U2} of the upper wafer W_{U}, as will be described later. That is, the sensors 250a and 250b correspond to a speed measurement device in the present disclosure.

The lower chuck 220, like the upper chuck 210, is of a pin chuck type. The lower chuck 220 has a main body 260 having a diameter equal to or larger than the diameter of the lower wafer W_{L} when viewed from the top. A plurality of pins 261 are provided on a top surface of the main body 260 to be in contact with the rear surface W_{L2} of the lower wafer W_{L}. Further, an outer rib 262 having the same height as the pins 261 is provided at an outer peripheral portion of the top surface of the main body 260 to support an outer peripheral portion of the rear surface W_{L2} of the lower wafer W_{L}. The outer rib 262 is provided in an annular shape outside the plurality of pins 261.

Further, on the top surface of the main body 260, an inner rib 263 having the same height as the pins 261 is provided inside the outer rib 262 to support the rear surface W_{L2} of the lower wafer W_{L}. The inner rib 263 is provided in an annular shape to be concentric with the outer rib 262. Further, an area 264 (hereinafter, sometimes referred to as suction area 264) inside the outer rib 262 is partitioned into a first suction area 264a inside the inner rib 263 and a second suction area 264b outside the inner rib 263.

A first suction opening 265a for evacuating the lower wafer W_{L} in the first suction area 264a is formed in the top surface of the main body 260. For example, the first suction opening 265a is formed at one location in the first suction area 264a, for example. A first suction pipe 266a provided inside the main body 260 is connected to the first suction opening 265a. Further, a non-illustrated vacuum pump is connected to the first suction pipe 266a.

Further, a second suction opening 265b for evacuating the lower wafer W_{L} in the second suction area 264b is also formed in the top surface of the main body 260. For example, the second suction opening 265b is plural in number, and these second suction openings 265b are formed at multiple locations in the second suction area 264b. A second suction pipe 266b provided inside the main body 260 is connected to the second suction opening 265b. Further, a non-illustrated vacuum pump is connected to the second suction pipe 266b.

The suction areas 264a and 264b surrounded by the lower wafer W_{L}, the main body 260, and the outer rib 262 are decompressed by being evacuated through the suction openings 265a and 265b, respectively. The lower chuck 220 is configured to be capable of attracting and holding the lower wafer W_{L} in each of the first suction area 264a and the second suction area 264b individually.

In the lower chuck 220, non-illustrated through holes are formed through the main body 260 in a thickness direction thereof at, for example, three locations in the vicinity of a center of the main body 260. Elevating pins provided below the moving device 223 are inserted into these through holes.

In a peripheral portion of the main body 260, a non-illustrated guide member is provided to suppress the wafers W_{U} and W_{L} and the combined wafer W_{T} from sticking out of or sliding down from the lower chuck 220. The guide member is plural in number, and these guide members are provided at a plurality of, e.g., four locations on the outer peripheral portion of the main body 260 at an equal distance therebetween.

Furthermore, the bonding apparatus 41 may be equipped with a non-illustrated inverting device to invert the front surface and the rear surface of the upper wafer W_{U} transferred to the bonding apparatus 41 and attracted and held by the upper chuck 210. The upper wafer W_{U} is transferred to the bonding apparatus 41 in a state where the front surface W_{U1}, on which the surface modifying processing and the surface hydrophilizing processing have been performed, faces upwards. Since the front surface and the rear surface of the upper wafer W_{U} is inverted by the inverting device, the rear surface W_{U2} can be held by the upper chuck 210 appropriately.

However, the arrangement of the inverting device is not limited thereto. A non-illustrated inverting device configured to invert the front surface and the rear surface of the upper wafer W_{U} may be provided independently at a certain position in the processing station 3 of the bonding system 1 instead of inside the bonding apparatus 41.

The bonding apparatus 41 is configured as described above. The above-described configuration is just an example, and the bonding apparatus 41 may have any configuration as long as it can bond the front surface W_{U1} of the upper wafer W_{U} with the front surface W_{L1} of the lower wafer W_{L}.

### Bonding Method

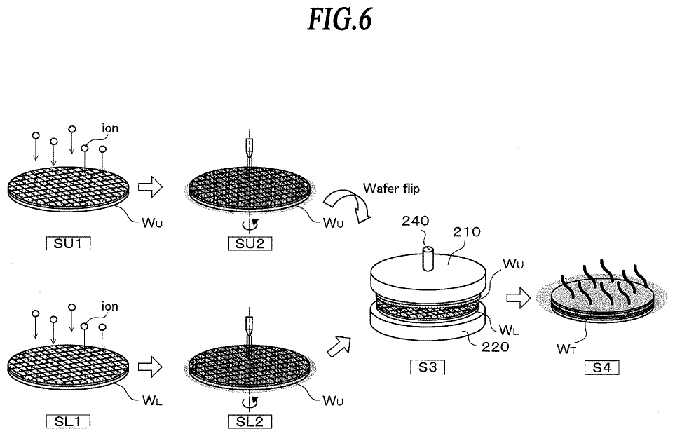

Hereinafter, a method of bonding the upper wafer W_{U} and the lower wafer W_{L} by using the bonding system 1 configured as described above will be described. FIG. 6 is an explanatory diagram illustrating main processes of a wafer processing performed in the bonding system 1.

First, a cassette C_{U} accommodating a plurality of upper wafers W_{U}, a cassette C_{L} accommodating a plurality of lower wafers W_{L} and an empty cassette C_{T} are placed on respective cassette placing plates 11 of the carry-in/out station 2. Then, an upper wafer W_{U} is taken out of the cassette C_{U} by the wafer transfer device 22 and transferred to the transition device 50 of the processing station 3.

Subsequently, the upper wafer W_{U} is transferred into the surface modifying apparatus 30 by the wafer transfer device 62. In the surface modifying apparatus 30, an oxygen gas or a nitrogen gas as a processing gas is excited and formed into a plasma to be ionized in a desired depressurized atmosphere. The oxygen ions or nitrogen ions are radiated onto the front surface W_{U1} of the upper wafer W_{U}, and the front surface W_{U1} is plasma-processed. As a result, the front surface W_{U1} of the upper wafer W_{U} is modified (process SU1 in FIG. 6).

Then, the upper wafer W_{U} is transferred into the surface hydrophilizing apparatus 40 by the wafer transfer device 62. In the surface hydrophilizing apparatus 40, pure water is supplied onto the upper wafer W_{U} while rotating the upper wafer W_{U} held by the spin chuck. The supplied pure water is spread on the front surface W_{U1} of the upper wafer W_{U}, and hydroxyl groups (silanol groups) adhere to the front surface W_{U1} of the upper wafer W_{U} modified in the surface modifying apparatus 30, so that the front surface W_{U1} is hydrophilized. Further, the front surface W_{U1} of the upper wafer W_{U} is cleaned with the pure water (process SU2 in FIG. 6).

Thereafter, the upper wafer W_{U} is transferred into the bonding apparatus 41 by the wafer transfer device 62. The front surface and the rear surface of the upper wafer W_{U} carried into the bonding apparatus 41 are inverted by the non-illustrated inverting device. Also, in this case, a position of the upper wafer W_{U} in the horizontal direction is adjusted by a non-illustrated position adjusting mechanism. Thereafter, the rear surface W_{U2} is attracted to and held by the upper chuck 210. To elaborate, the upper wafer W_{U} is evacuated in the suction areas 234a and 234b through the suction openings 235a and 235b, so that the upper wafer W_{U} is attracted to and held by the upper chuck 210.

While the above-described processings are performed on the upper wafer W_{U}, processings are performed on the lower wafer W_{L}. First, the lower wafer W_{L} is taken out of the cassette C_{L} and transferred into the transition device 50 of the processing station 3 by the wafer transfer device 22.

Thereafter, the lower wafer W_{L} is transferred into the surface modifying apparatus 30 by the wafer transfer device 62, and the front surface W_{L1} of the lower wafer W_{L} is modified (process SL1 in FIG. 6). Further, the modification of the front surface W_{L1} of the lower wafer W_{L} in the process SL1 is the same as the above-described process SU1.

Then, the lower wafer W_{L} is transferred into the surface hydrophilizing apparatus 40 by the wafer transfer device 62, and the front surface W_{L1} of the lower wafer W_{L} is hydrophilized and cleaned (process SL2 in FIG. 6). Further, the hydrophilization and cleaning of the front surface W_{L1} of the lower wafer W_{L} in the process SL2 is the same as the above-described process SU2.

Thereafter, the lower wafer W_{L} is transferred into the bonding apparatus 41 by the wafer transfer device 62. The rear surface W_{L2} of the lower wafer W_{L} carried into the bonding apparatus 41 is attracted to and held by the lower chuck 220 after a position of the lower wafer W_{L} in the horizontal direction is adjusted by a non-illustrated position adjusting mechanism. To elaborate, the lower wafer W_{L} is evacuated in the suction areas 264a and 264b through the suction openings 265a and 265b, so that the lower wafer W_{L} is attracted to and held by the lower chuck 220.

Next, positions of the upper wafer W_{U} held by the upper chuck 210 and the lower wafer W_{L} held by the lower chuck 220 are adjusted in the horizontal direction. Specifically, predetermined reference points on the front surface W_{L1} of the lower wafer W_{L} held by the lower chuck 220 are imaged in sequence by the upper imaging device 212, and predetermined reference points on the front surface W_{U1} of the upper wafer W_{U} held by the upper chuck 210 are imaged in sequence by the lower imaging device 222. The obtained images are outputted to the control device 70. In the control device 70, the upper chuck 210 (the upper wafer W_{U}) is rotated by the rotating device 214, and the lower chuck 220 (the lower wafer W_{L}) is moved by the moving device 223 so that the reference points of the upper wafer W_{U} overlap the reference points of the lower wafer W_{L}, respectively, based on the images obtained by the upper imaging device 212 and the lower imaging device 222. In this way, the upper wafer W_{U} and the lower wafer W_{L} are position-adjusted and arranged at desired positions to face each other.

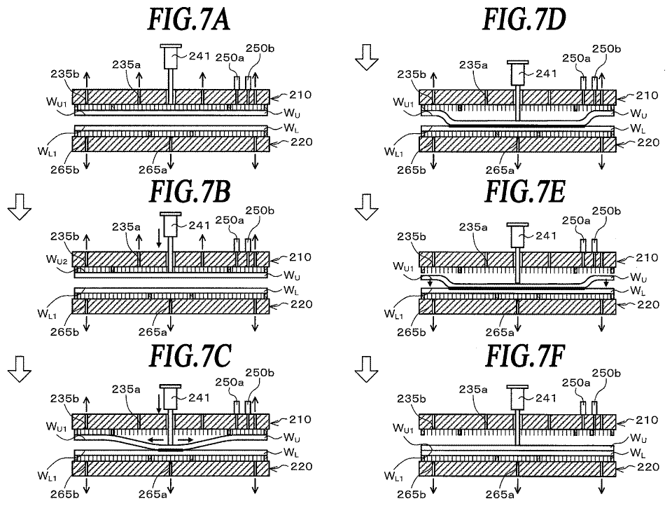

Thereafter, positions of the upper wafer W_{U} held by the upper chuck 210 and the lower wafer W_{L} held by the lower chuck 220 are adjusted in the vertical direction. Specifically, the lower chuck 220 is moved in the vertical direction by the moving device 223 to adjust the positions of the upper wafer W_{U} and the lower wafer W_{L} in the vertical direction. In this way, the upper wafer W_{U} and the lower wafer W_{L} are arranged at required positions to face each other, as illustrated in FIG. 7A.

Then, a bonding processing is performed to bond the upper wafer W_{U} and the lower wafer W_{L} (process S3 in FIG. 6). To elaborate, the actuator 241 is first lowered by the cylindrical member 242 to allow the actuator 241 to come into contact with the central portion of the rear surface W_{U2} of the upper wafer W_{U}, as illustrated in FIG. 7B.

Thereafter, as shown in FIG. 7C, the actuator 241 is continuously lowered, and, thus, the central portion of the upper wafer W_{U} is pressed to be lowered. As a result, the central portion of the upper wafer W_{U} and the central portion of the lower wafer W_{L} are brought into contact with each other and pressed against each other. At this time, the evacuation of the upper wafer W_{U} through the first suction opening 235a in the first suction area 234a is stopped, and the second suction area 234b is evacuated through the second suction opening 235b. Then, the outer peripheral portion of the upper wafer W_{U} is held by the upper chuck 210.

When the central portion of the upper wafer W_{U} and the central portion of the lower wafer W_{L} are brought into contact with each other and pressed against each other, bonding of the upper wafer W_{U} and the lower wafer W_{L} is started between the central portions (marked with a thick line in FIG. 7C). That is, since the front surface W_{U1} of the upper wafer W_{U} and the front surface W_{L1} of the lower wafer W_{L} have been modified in the processes SU1 and SL1, respectively, a van der Waals force (intermolecular force) is generated between the front surfaces W_{U1} and W_{L1}, and, thus, the front surfaces W_{U1} and W_{L1} are bonded to each other. Also, since the front surface W_{U1} of the upper wafer W_{U} and the front surface W_{L1} of the lower wafer W_{L} have been hydrophilized in the processes SU2 and SL2, respectively, the hydrophilic groups between the front surfaces W_{U1} and W_{L1} are hydrogen-bonded (which generates an intermolecular force). Thus, the front surfaces W_{U1} and W_{L1} are strongly bonded to each other. Here, as the bonding between the front surfaces W_{U1} and W_{L1} caused by the van der Waals force and the hydrogen bonding is expanded from the central portions toward the outer peripheral portions of the front surfaces W_{U1} and W_{L1}, a bonding wave is generated, as illustrated in FIG. 7D.

Afterwards, the evacuation of the upper wafer W_{U} through the second suction opening 235b in the second suction area 234b is stopped in the state that the central portion of the upper wafer W_{U} and the central portion of the lower wafer W_{L} are pressed by the pressing device 240 as illustrated in FIG. 7E. As a result, the outer peripheral portion of the upper wafer W_{U} falls onto the lower wafer W_{L}. Then, the entire front surface W_{U1} of the upper wafer W_{U} and the entire front surface W_{L1} of the lower wafer W_{L} come into contact with each other as shown in FIG. 7F, so that the upper wafer W_{U} and the lower wafer W_{L} are bonded.

The combined wafer W_{T} obtained by bonding the upper wafer W_{U} and the lower wafer W_{L} is transferred to the warpage measurement device 52 by the wafer transfer device 62, and a warpage amount of the combined wafer W_{T} is measured. Then, the combined wafer W_{T} is transferred to the cassette C_{T} by the wafer transfer device 22 of the carry-in/out station 2. In this way, the series of processes of the bonding processing for the upper wafer W_{U} and the lower wafer W_{L} are completed.

Also, the combined wafer W_{T} obtained by bonding the upper wafer W_{U} and the lower wafer W_{L} is heated (annealed) by a heating apparatus provided outside the bonding system 1 (process S4 in FIG. 6). This heating processing may be performed outside the bonding system 1 in this way. However, the heating processing may be performed by a non-illustrated heating apparatus provided in the processing station 3 of the bonding system 1 after bonding of the upper wafer W_{U} and the lower wafer W_{L} in the bonding apparatus 41.

In addition, the rear surface W_{U2} of the heated combined wafer W_{T} is then subjected to a grinding processing in a grinding apparatus provided outside the bonding system 1, and is also subjected to an etching processing in an etching apparatus provided outside the bonding system 1. Then, the combined wafer W_{T} is thinned.

### Estimation Method of Boding Strength

Now, an estimation method of bonding strength of the bonded combined wafer W_{T} as described above will be described in two exemplary embodiments. In the following description, bonding strength of the combined wafer W_{T} after being subjected to the heating processing is estimated as the bonding strength of the combined wafer W_{T}.

### First Exemplary Embodiment

In the first exemplary embodiment, the bonding strength of the combined wafer W_{T} is estimated based on bonding speed (propagation speed of the bonding wave).

In the bonding apparatus 41, by generating the bonding wave that spreads from the central portions toward the outer peripheral portions the upper wafer W_{U} and the lower wafer W_{L}, the upper and lower wafers W_{U} and W_{L} are bonded. At this time, since the height of the rear surface W_{U2} of the upper wafer W_{U} is displaced, the bonding speed, which is the propagation speed of the bonding wave, is measured based on this height position.

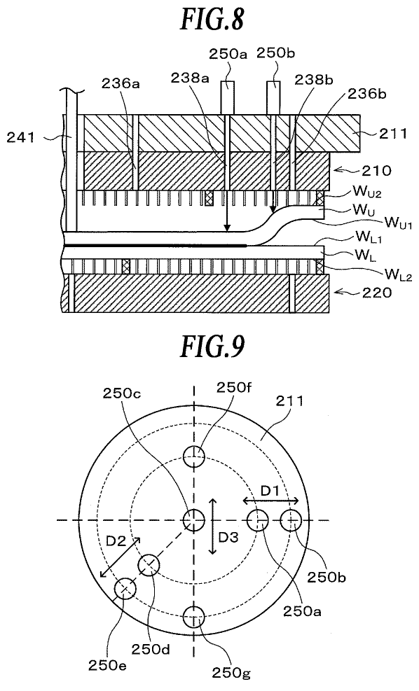

As illustrated in FIG. 8, the sensors 250a and 250b measure the height position of the rear surface W_{U2} of the upper wafer W_{U}. Specifically, the sensors 250a and 250b radiate LED light to the rear surface W_{U2} of the upper wafer W_{U} through the transmission windows 238a and 238b and receive reflected light from the rear surface W_{U2} to measure the height position of the rear surface W_{U2}. Measurement results of the sensors 250a and 250b are outputted to the control device 70. Further, the transmission windows 238a and 238b may be omitted, and a through hole (not shown) may be formed through the main body 230 of the upper chuck 210 and the upper chuck stage 211. In this case, the LED light from the sensors 250a and 250b is radiated to the rear surface W_{U2} of the upper wafer W_{U} after passing through the through hole.

The control device 70 calculates the bonding speed based on the height position of the rear surface W_{U2} of the upper wafer W_{U}. Specifically, the control device 70 detects the bonding wave from the height position of the rear surface W_{U2} of the upper wafer W_{U}. For example, when the height position of the rear surface W_{U2} of the upper wafer W_{U} reaches the position when the upper wafer W_{U} and the lower wafer W_{L} are bonded, it is detected that the bonding wave has arrived. Then, the time from when the bonding wave arrives at the position of the first sensor 250a until the bonding wave arrives at the position of the second sensor 250b is calculated, and the bonding speed is calculated from a previously known distance between the sensors 250a and 250b.

The bonding wave propagates concentrically from a center toward a periphery. For this reason, if the bonding speed between the two sensors 250a and sensors 250b arranged in the diametrical direction at least is measured, this bonding speed represents the bonding speed of the bonding wave.

Additionally, as shown in FIG. 9, three or more sensors 250a to 250g may be provided on the top surface of the upper chuck stage 211.

For example, the sensor 250c is placed at the center. In this case, bonding speed between the sensors 250c, 250a, and 250b can be measured in a diametrical direction D1. Further, in comparison of the bonding speed between the sensors 250c and 250a with the bonding speed between the sensors 250a and 250b, it is desirable to measure the bonding speed between the sensors 250a and 250b on the peripheral sides. Since the central portion of the upper wafer W_{U} and the central portion of the lower wafer W_{L} are pressurized by the actuator 241, the bonding wave between the sensors 250c and 250a is affected by this pressurization at the central portions. For this reason, it is desirable to measure the bonding speed between the sensors 250a and 250b that are disposed apart from the actuator 241. In addition, the inner rib 233 exists between the sensors 250c and 250a, and there is a risk that the measurement of the bonding speed may be affected by individual differences between the vacuum pump communicating with the first suction opening 235a at the inside of the inner rib 233 and the vacuum pump communicating with the second suction opening 235b at the outside of the inner rib 233. In this regard, since there is no inner rib between the sensors 250a and 250b, that is, since the sensors 250a and 250b are provided in the same second suction area 234b, the bonding speed can be measured without being affected by such individual difference in the vacuum pumps.

For example, the sensors 250d and 250e are arranged in this order in a diametrical direction D2. The sensor 250d is disposed on the same circumference as the sensor 250a, and the sensor 250e is disposed on the same circumference as the sensor 250b. In this case, bonding speed between the sensors 250d and 250e can be measured in the diametrical direction D2. Further, in the diametrical directions D1 and D2, crystal orientation may differ between a cross direction and a diagonal direction of the upper wafer W_{U}. If the crystal orientation is different in this way, the bonding speed may be different in the diametrical directions D1 and D2. In such a case, an average value of the bonding speed in the diametrical direction D1 and the bonding speed in the diametrical direction D2 may be calculated, and this average value may be used as the bonding speed of the bonding wave. In this case, the bonding speed can be measured more accurately.

For example, the sensors 250f and 250g are arranged on opposite sides with respect to a center in a diametrical direction D3. The sensor 250f is disposed on the same circumference as the sensor 250a, and the sensor 250g is disposed on the same circumference as sensor 250b. In this case, bonding speed between the sensors 250f and 250g can be measured in the diametrical direction D3. By measuring the bonding speeds in the multiple diametrical directions D1, D2 and D3 in this way, the number of measurements of the bonding speed increases, so that more accurate measurement of the bonding speed is enabled.

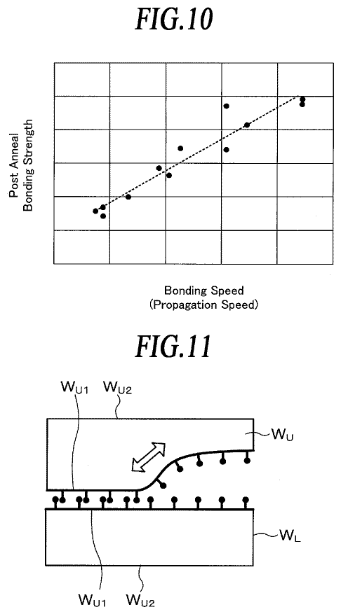

Here, the present inventors have conductive intensive research and found that there is a correlation between the bonding speed, which is the propagation speed of the bonding wave, and the bonding strength of the combined wafer W_{T} after being subjected to the heating processing. FIG. 10 is an explanatory diagram showing a relationship between bonding speed (horizontal axis) and bonding strength (vertical axis). The present inventors have investigated bonding speeds and bonding strengths for a plurality of combined wafers W_{T} and plotted them in FIG. 10. Referring to FIG. 10, there is a correlation indicated by a dashed line.

Therefore, prior to the wafer processing of the combined wafer W_{T}, a first correlation between bonding speed and bonding strength is acquired and stored as database. At this time, the bonding strength of the combined wafer W_{T} after being subjected to the heat processing is measured by using, for example, a conventional blade insertion method. The first correlation is obtained for each characteristic of the front surface W_{U1} of the upper wafer W_{U} and the front surface W_{L1} of the lower wafer W_{L}, for example. Further, the first correlation is acquired for each plasma processing condition in the surface modifying apparatus 30, for example. Then, the bonding speed when bonding the upper wafer W_{U} and the lower wafer W_{L} is measured. Based on this measured bonding speed, the bonding speed of the combined wafer W_{T} after being bonded can be estimated from the first correlation in the bonding speed database.

### Second Exemplary Embodiment

In the second exemplary embodiment, bonding strength of the bonded combined wafer W_{T} is estimated based on a warpage amount of the combined wafer W_{T}.

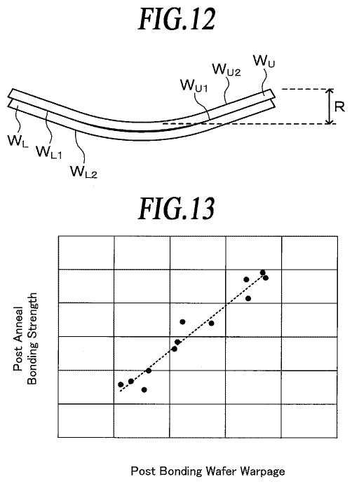

In the bonding apparatus 41, the bonding wave that spreads from the center toward the periphery is generated as described above to bond the upper wafer W_{U} and the lower wafer W_{L}. At this time, since the central portion of the upper wafer W_{U} is lowered onto the central portion of the lower wafer W_{L} by the pressing device 240, the upper wafer W_{U} warps downwards in a convex manner and is stretched, as shown in FIG. 11. Specifically, during the bonding, the air present between the upper wafer W_{U} and the lower wafer W_{L} is pushed out from a center to a periphery. At this time, since the lower wafer W_{L} is fixed by being attracted to and held by the lower chuck 220 while the upper wafer W_{U} is separated from the upper chuck 210 and is not fixed thereto, the upper wafer W_{U} is stretched (in a direction marked by an arrow in FIG. 11) by the viscosity of the air. In this case, even if the central portions of the upper wafer W_{U} and the lower wafer W_{L} are coincident, a phenomenon in which positional misalignment occurs in a horizontal direction, that is, so-called scaling occurs at the outer peripheral portions thereof. Also, the combined wafer W_{T} warps downwards in a convex manner due to the elongation of the upper wafer W_{U}, as illustrated in FIG. 12.

The warpage measurement device 52 measures a warpage amount of the bonded combined wafer W_{T}. As shown in FIG. 12, a warpage amount R is a difference between the height position of the central portion and the height position of the outer peripheral portion of the rear surface W_{U2} of the upper wafer W_{U}.

Here, the present inventors conducted intensive research and found that there is a correlation between a warpage amount of the combined wafer W_{T} and bonding strength of the combined wafer W_{T} after being subjected to the heating processing. FIG. 13 is an explanatory diagram showing a relationship between a warpage amount (horizontal axis) and bonding strength (vertical axis). The present inventors investigated warpage amounts and bonding strengths for a plurality of combined wafers W_{T} and plotted them in FIG. 13. Referring to FIG. 13, there is a correlation marked by a dashed line.

Therefore, prior to the wafer processing of the combined wafer W_{T}, a second correlation between the warpage amount and the bonding strength is acquired and stored as database. At this time, the bonding strength of the combined wafer W_{T} after being subjected to the heating processing is measured by using, for example, a conventional blade insertion method. The second correlation is obtained for each characteristic of the front surface W_{U1} of the upper wafer W_{U} and the front surface W_{L1} of the lower wafer W_{L}, for example. Further, the second correlation is obtained for each plasma processing condition in the surface modifying apparatus 30, for example. Then, the warpage amount of the combined wafer W_{T} is measured in the warpage measurement device 52. Based on this measured warpage amount, the bonding strength of the combined wafer W_{T} after being bonded can be estimated from the second correlation in the database.

In addition, a flat chuck with a flat surface or a transformation chuck with a surface transformed convexly upwards is used as an example of the lower chuck 220. When the transformation chuck is used, the lower wafer W_{L} is transformed convexly, so the aforementioned scaling is corrected, and warpage of the combined wafer W_{T} after being bonded is suppressed. Meanwhile, when the flat chuck is used, the lower wafer W_{L} is maintained flat, so scaling occurs and the combined wafer W_{T} after being bonded warps. For this reason, the second exemplary embodiment is useful when the flat chuck is used as the lower chuck 220.

As described above, according to the first exemplary embodiment, the bonding strength of the combined wafer W_{T} can be estimated based on the first correlation between the bonding speed during the bonding and the bonding strength of the combined wafer W_{T}. Furthermore, according to the second exemplary embodiment, the bonding strength of the combined wafer W_{T} can be estimated based on the second correlation between the warpage amount of the combined wafer W_{T} after being bonded and the bonding strength of the combined wafer W_{T}. In any of these exemplary embodiments, the bonding strength of the combined wafer W_{T} can be easily estimated without using the conventional blade insertion method. As a result, there is no need to prepare a conventional measurement wafer, and the bonding strength of the combined wafer W_{T} as a product can be estimated in a non-destructive way. For this reason, waste that may be caused when using the conventional blade insertion method can be suppressed.

In addition, in the conventional blade insertion method, a simple patternless measurement wafer is used. According to the above-described exemplary embodiments, however, the bonding strength of the combined wafer W_{T} as a product can be estimated. For this reason, measurement accuracy for the actual bonding strength can be improved.

Moreover, the above-described first and second exemplary embodiments may be combined. That is, a third correlation between bonding strength of the combined wafer W_{T} and a combination of bonding speed during the bonding and a warpage amount of the combined wafer W_{T} after being bonded is acquired and stored as database. Then, a bonding speed when bonding the upper wafer W_{U} and the lower wafer W_{L} is measured in the bonding apparatus 41, and a warpage amount of the combined wafer W_{T} is measured in the warpage measurement device 52. Based on these measured bonding speeds and warpage amounts, the bonding strength of the combined wafer W_{T} after being bonded can be estimated from the third correlation in the database. In this case, the bonding strength can be estimated with higher precision.

Further, in the above-described exemplary embodiments, the warpage amount of the combined wafer W_{T} after being bonded is measured by the warpage measurement device 52. However, a warpage measurer may be provided in the bonding apparatus 41, and the warpage amount of the combined wafer W_{T} may be measured by this warpage measurer. Alternatively, the warpage amount of the combined wafer W_{T} may be measured by a warpage measurement device provided outside the bonding system 1.

In addition, in the above-described exemplary embodiments, the first correlation, the second correlation, and the third correlation are obtained by using the measurements of the bonding strength of the combined wafer W_{T} after being subjected to the heating processing. However, measurements of the bonding strength of the combined wafer W_{T} before being subjected to the heating processing may be used instead. In this case, the bonding strength of the combined wafer W_{T} after being bonded and before being subjected to the heating processing can be estimated.

### Methods of Utilizing Estimated Bonding Strength

Now, a method of utilizing the bonding strength of the combined wafer W_{T} estimated as described above will be explained.

### First Utilization Method

Based on the estimated bonding strength of the combined wafer W_{T}, a bonding state of the combined wafer W_{T} may be determined. For example, the bonding strength is compared with a predetermined threshold value, and if the bonding strength is equal to or larger than the threshold value, the combined wafer W_{T} is determined to be normal. If the bonding strength is less than the threshold value, on the other hand, the combined wafer W_{T} is determined to be abnormal.

If the combined wafer W_{T} is determined to be abnormal, an alarm may be set off and the subsequent wafer processing may be stopped. Alternatively, a flag indicating that the combined wafer W_{T} is abnormal may be set up to distinguish it from a normal combined wafer W_{T}, and the subsequent wafer processing may be continued. Furthermore, if the combined wafer W_{T} is determined to be abnormal, a pre-process of the bonding processing may be inspected. As an inspection of the pre-process, plasma processing conditions in the surface modifying apparatus 30 of the bonding system 1 may be inspected, for example. Alternatively, conditions when performing a film forming processing on the front surface W₁ of the wafer W outside the bonding system 1 or conditions when polishing the front surface W₁ may be inspected.

### Second Utilization Method

Based on the estimated bonding strength of the combined wafer W_{T}, processing conditions for each processing may be feedback-controlled.

For example, based on the bonding strength of the combined wafer W_{T}, bonding conditions when performing the bonding processing of the process S3 in the bonding apparatus 41 are feedback-controlled. The bonding conditions that are feedback-controlled include, by way of example, an attracting pressure for the upper wafer W_{U} in the upper chuck 210, an attracting pressure for the lower wafer W_{L} in the lower chuck 220, a stroke (moving distance) of the actuator 241 of the pressing device 240, a pressure when pressing the central portions of the wafers W_{U} and W_{L} by the pressing device 240, a distance between the wafers W_{U} and W_{L} after the adjustment of their positions in the vertical direction, etc.

For example, based on the bonding strength of the combined wafer W_{T}, plasma processing conditions (modification conditions) when performing the surface modifying processing of the processes SU1 and SU2 in the surface modifying apparatus 30 are feedback-controlled. The plasma processing conditions that are feedback-controlled include, for example, a source power of the high frequency power supply 132, a pressure inside the processing container 100, a processing time of the plasma processing, a flow rate of a processing gas supplied from the processing gas supply 110, etc.

### Third Utilization Method

The control device 70 may output information on the estimated bonding strength of the combined wafer W_{T} to an apparatus that performs a post-process of the bonding processing.

The apparatus that performs the post-process is not particularly limited. For example, it may be a separating apparatus. In the separating apparatus, a blade is inserted into a bonding interface of the thinned combined wafer W_{T} to separate it into the upper wafer W_{U} and the lower wafer W_{L}, and the upper wafer W_{U} is removed from the lower wafer W_{L} by being held and moved on a pad. At this time, separation conditions are feedforward controlled based on the outputted bonding strength. The separation conditions that are feedforward controlled include, by way of non-limiting example, a blade insertion speed, a pad moving speed (separation speed), a pad movement position, etc.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

Moreover, the following configuration examples also fall within the technical scope of the present disclosure.

(1) A bonding method of bonding substrates to each other, comprising:
forming a combined substrate by gradually bonding, with a central portion of a first substrate and a central portion of a second substrate in contact with each other, the first substrate and the second substrate from the central portions toward outer peripheral portions thereof;
measuring a bonding speed in the bonding from the central portions toward the outer peripheral portions; and
estimating, based on the measured bonding speed, bonding strength of the bonded combined substrate from a relationship between bonding speed and bonding strength.

(2) The bonding method described in (1),
wherein in the measuring of the bonding speed, a bonding speed between two points in a diametrical direction between the central portion and the outer peripheral portion is measured.

(3) The bonding method described in (2),
wherein in the measuring of the bonding speed, the bonding speed between the two points on a side of the outer peripheral portion not including the central portion at least is measured.

(4) The bonding method described in (3),
wherein the two points in the measuring of the bonding speed are provided in a same suction area where the first substrate is evacuated.

(5) The bonding method described in any one of (2) to (4),
wherein in the measuring of the bonding speed, the bonding speed between the two points in each of multiple diametrical directions, which correspond to different crystal orientations in the first substrate, is measured.

(6) The bonding method described in any one of (1) to (5), further comprising:
measuring a warpage amount of the bonded combined substrate; and
estimating, based on the measured bonding speed and warpage amount, the bonding strength of the bonded combined substrate from a relationship between bonding strength and a combination of bonding speed and warpage amount.

(7) A bonding method of bonding substrates to each other, comprising:
forming a combined substrate by gradually bonding, with a central portion of a first substrate and a central portion of a second substrate in contact with each other, the first substrate and the second substrate from the central portions toward outer peripheral portions thereof;
measuring a warpage amount of the bonded combined substrate; and
estimating, based on the measured warpage amount, bonding strength of the bonded combined substrate from a relationship between warpage amount and bonding strength.

(8) The bonding method described in any one of (1) to (7),
wherein a bonding state of the combined substrate is determined based on the estimated bonding strength of the combined substrate.

(9) The bonding method described in any one of (1) to (8),
wherein a bonding condition when bonding the first substrate and the second substrate is controlled based on the estimated bonding strength of the combined substrate.

(10) The bonding method described in any one of (1) to (9), further comprising:
modifying, prior to the bonding of the first substrate and the second substrate, at least one of a front surface of the first substrate or a front surface of the second substrate by plasma of a processing gas,
wherein a modification condition when modifying the at least one of the front surface of the first substrate or the front surface of the second substrate is controlled based on the estimated bonding strength of the combined substrate.

(11) The bonding method described in any one of (1) to (10),
wherein information on the estimated bonding strength of the combined substrate is outputted to a processing apparatus configured to process the bonded combined substrate.

(12) A bonding system of bonding substrates to each other, comprising:
a bonding apparatus configured to form a combined substrate by gradually bonding, with a central portion of a first substrate and a central portion of a second substrate in contact with each other, the first substrate and the second substrate from the central portions toward outer peripheral portions thereof;
a speed measurer configured to measure a bonding speed in the bonding from the central portions toward the outer peripheral portions; and
a control device configured to estimate, based on the measured bonding speed, bonding strength of the bonded combined substrate from a relationship between bonding speed and bonding strength.

(13) The bonding system described in (12),
wherein the speed measurer measures a bonding speed between two points in a diametrical direction between the central portion and the outer peripheral portion.

(14) The bonding system described in (13),
wherein the speed measurer measures the bonding speed between the two points on a side of the outer peripheral portion not including the central portion at least.

(15) The bonding system described in any one of (12) to (14), further comprising:
a warpage measurer configured to measure a warpage amount of the bonded combined substrate,
wherein the control device estimates, based on the measured bonding speed and warpage amount, the bonding strength of the bonded combined substrate from a relationship between bonding strength and a combination of bonding speed and warpage amount.

(16) A bonding system of bonding substrates to each other, comprising:
a bonding apparatus configured to form a combined substrate by gradually bonding, with a central portion of a first substrate and a central portion of a second substrate in contact with each other, the first substrate and the second substrate from the central portions toward outer peripheral portions thereof;
a warpage measurer configured to measure a warpage amount of the bonded combined substrate; and
a control device configured to estimate, based on the measured warpage amount, bonding strength of the bonded combined substrate from a relationship between warpage amount and bonding strength.

(17) The bonding system described in any one of (12) to (16),
wherein the control device determines a bonding state of the combined substrate based on the estimated bonding strength of the combined substrate.

(18) The bonding system described in any one of (12) to (17),
wherein the control device controls, based on the estimated bonding strength of the combined substrate, a bonding condition when bonding the first substrate and the second substrate.

(19) The bonding system described in any one of (12) to (18), further comprising:
a modifying apparatus configured to modify, before bonding the first substrate and the second substrate in the bonding apparatus, at least one of a front surface of the first substrate or a front surface of the second substrate by plasma of a processing gas,
wherein the control device controls, based on the estimated bonding strength of the combined substrate, a modification condition when modifying the at least one of the front surface of the first substrate or the front surface of the second substrate.

(20) The bonding system described in any one of (12) to (19),
wherein the control device outputs information on the estimated bonding strength of the combined substrate to a processing apparatus configured to process the bonded combined substrate.

According to the exemplary embodiment, it is possible to easily estimate the bonding strength of the combined substrate in which the substrates are bonded to each other.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A bonding method of bonding substrates to each other, comprising:
forming a combined substrate by gradually bonding, with a central portion of a first substrate and a central portion of a second substrate in contact with each other, the first substrate and the second substrate from the central portions toward outer peripheral portions thereof;
measuring a bonding speed in the bonding from the central portions toward the outer peripheral portions; and
estimating, based on the measured bonding speed, bonding strength of the bonded combined substrate from a relationship between bonding speed and bonding strength.

2. The bonding method of claim 1,
wherein in the measuring of the bonding speed, a bonding speed between two points in a diametrical direction between the central portion and the outer peripheral portion is measured.

3. The bonding method of claim 2,
wherein in the measuring of the bonding speed, the bonding speed between the two points on a side of the outer peripheral portion not including the central portion at least is measured.

4. The bonding method of claim 3,
wherein the two points in the measuring of the bonding speed are provided in a same suction area where the first substrate is evacuated.

5. The bonding method of claim 2,
wherein in the measuring of the bonding speed, the bonding speed between the two points in each of multiple diametrical directions, which correspond to different crystal orientations in the first substrate, is measured.

6. The bonding method of claim 1, further comprising:
measuring a warpage amount of the bonded combined substrate; and
estimating, based on the measured bonding speed and warpage amount, the bonding strength of the bonded combined substrate from a relationship between bonding strength and a combination of bonding speed and warpage amount.

7. The bonding method of claim 1,
wherein a bonding state of the combined substrate is determined based on the estimated bonding strength of the combined substrate.

8. The bonding method of claim 1,
wherein a bonding condition when bonding the first substrate and the second substrate is controlled based on the estimated bonding strength of the combined substrate.

9. The bonding method of claim 1, further comprising:
modifying, prior to the bonding of the first substrate and the second substrate, at least one of a front surface of the first substrate or a front surface of the second substrate by plasma of a processing gas,
wherein a modification condition when modifying the at least one of the front surface of the first substrate or the front surface of the second substrate is controlled based on the estimated bonding strength of the combined substrate.

10. The bonding method of claim 1,
wherein information on the estimated bonding strength of the combined substrate is outputted to a processing apparatus configured to process the bonded combined substrate.

11. A bonding system of bonding substrates to each other, comprising:
a bonding apparatus configured to form a combined substrate by gradually bonding, with a central portion of a first substrate and a central portion of a second substrate in contact with each other, the first substrate and the second substrate from the central portions toward outer peripheral portions thereof;
a speed measurer configured to measure a bonding speed in the bonding from the central portions toward the outer peripheral portions; and
a control device configured to estimate, based on the measured bonding speed, bonding strength of the bonded combined substrate from a relationship between bonding speed and bonding strength.

12. The bonding system of claim 11,
wherein the speed measurer measures a bonding speed between two points in a diametrical direction between the central portion and the outer peripheral portion.

13. The bonding system of claim 12,
wherein the speed measurer measures the bonding speed between the two points on a side of the outer peripheral portion not including the central portion at least.

14. The bonding system of claim 11, further comprising:
a warpage measurer configured to measure a warpage amount of the bonded combined substrate,
wherein the control device estimates, based on the measured bonding speed and warpage amount, the bonding strength of the bonded combined substrate from a relationship between bonding strength and a combination of bonding speed and warpage amount.

15. The bonding system of claim 11,
wherein the control device determines a bonding state of the combined substrate based on the estimated bonding strength of the combined substrate.

16. The bonding system of claim 11,
wherein the control device controls, based on the estimated bonding strength of the combined substrate, a bonding condition when bonding the first substrate and the second substrate.

17. The bonding system of claim 11, further comprising:
a modifying apparatus configured to modify, before bonding the first substrate and the second substrate in the bonding apparatus, at least one of a front surface of the first substrate or a front surface of the second substrate by plasma of a processing gas,
wherein the control device controls, based on the estimated bonding strength of the combined substrate, a modification condition when modifying the at least one of the front surface of the first substrate or the front surface of the second substrate.

18. The bonding system of claim 11,
wherein the control device outputs information on the estimated bonding strength of the combined substrate to a processing apparatus configured to process the bonded combined substrate.
